(19) United States
(12) Patent Application Publication
(10) Pub. No.: US 2024/0381778 A1
(43) Pub. Date: Nov. 14, 2024

(54) METHOD FOR REDUCING DAMAGE TO MAGNETIC TUNNEL JUNCTION OF MRAM

(71) Applicant: JIANGSU LEUVEN INSTRUMENTS CO., LTD., Xuzhou, Jiangsu (CN)

(72) Inventors: Yuxin YANG, Xuzhou, Jiangsu (CN); Jiahe LI, Xuzhou, Jiangsu (CN); Taiyan PENG, Xuzhou, Jiangsu (CN); Dongdong HU, Xuzhou, Jiangsu (CN); Kaidong XU, Xuzhou, Jiangsu (CN)

(73) Assignee: JIANGSU LEUVEN INSTRUMENTS CO., LTD., Xuzhou, Jiangsu (CN)

(21) Appl. No.: 18/681,819

(22) PCT Filed: Dec. 2, 2021
(86) PCT No.: PCT/CN2021/134976

§ 371 Date: Feb. 6, 2024

(30) Foreign Application Priority Data
Aug. 20, 2021 (CN) 202110962630.7

(51) Int. Cl. H10N 50/01; H10B 61/00; H10N 50/10; H10N 50/80

(52) U.S. Cl. CPC H10N 50/01; H10B 61/00; H10N 50/10; H10N 50/80

(57) ABSTRACT

A method for reducing damage to a magnetic tunnel junction (MTJ) of a magnetic random access memory (MRAM), comprising: providing a base structure, where the base structure comprises a substrate, a lower electrode, an MTJ layer, and an upper electrode, which are arranged in the above-listed sequence along a first direction, and the first direction is perpendicular to the substrate and points from the substrate to the lower electrode; performing first etching on a surface of the upper electrode facing away from the substrate until the lower electrode is exposed; pre-processing a sidewall of the MTJ layer to form a modified layer with a preset thickness through reaction at the sidewall of the MTJ layer; and performing second etching until the substrate is exposed.

This application claims priority to Chinese Patent Application No. 202110962630.7, titled “METHOD FOR REDUCING DAMAGE TO MAGNETIC TUNNEL JUNCTION OF MRAM”, filed on Aug. 20, 2021 with the China National Intellectual Property Administration, which is incorporated herein by reference in its entirety.

### FIELD

The present disclosure relates to the technical field of semiconductor-chip manufacture, and in particular to a method for reducing damage to a magnetic tunnel junction of a MRAM.

### BACKGROUND

Continuous development of science and technology engenders wide application of various memories in people's lives and work, which brings great convenience.

Magnetic random access memories (MRAMs) are a new type of random access memories in the market. The MRAMs have higher reading/writing speed than that of conventional flash memories, and have radiation resistance and non-volatility which are lacked in traditional dynamic random-access memories (DRAMs) and static random-access memories (SRAMs). The MRAMs alone can achieve various storage functions which once can be implemented only by a combination of the three traditional types of memories.

When being manufactured through conventional processes, a crystal structure at a sidewall of a magnetic tunnel junction (MTJ) in the MRAM would be damaged during the processing and thereby results in a failure of MRAM devices.

### SUMMARY

A method for reducing damage to a magnetic tunnel junction (MTJ) of a magnetic random access memory (MRAM) is provided according to embodiments of the present disclosure, which addresses the above issue. Technical solutions are as follows.

A method for reducing damage to MTJ of MRAM is provided according to an embodiment of the present disclosure. The method comprises: providing a base structure, where the base structure comprises a substrate, a lower electrode, an MTJ layer, and an upper electrode, which are arranged in the above-listed sequence along a first direction, and the first direction is perpendicular to the substrate and points from the substrate to the lower electrode; performing first etching on a surface of the upper electrode facing away from the substrate until the lower electrode is exposed; pre-processing a sidewall of the MTJ layer to form a modified layer with a preset thickness through reaction at the sidewall of the MTJ layer; and performing second etching until the substrate is exposed.

In one embodiment, performing the first etching comprises: performing the first etching on the surface of the upper electrode through ion beam etching, until the lower electrode is exposed, where in the ion beam etching, an incident angle of an ion beam ranges from 10° to 60°, energy of ions ranges from 50V to 600V, a bias voltage for accelerating the ions ranges from 50V to 1000V, a flow rate of a gas ranges from 10 sccm to 500 sccm, and the gas comprises one or more of: an inert gas, nitrogen, oxygen, a fluorine-based gas, an amine gas, carbon monoxide, carbon dioxide, and an alcohol gas.

In one embodiment, performing the first etching comprises: performing the first etching on the surface of the upper electrode through reactive ion etching, until the lower electrode is exposed, where in the reactive ion etching, power of a source electrode ranges from 500 W to 2000 W, power of a bias electrode ranges from 100 W to 2000 W, a pressure in an etching chamber ranges from 2 mT to 20 mT, a flow rate of a gas ranges from 10 sccm to 500 sccm, and the gas comprises one or more of: an inert gas, nitrogen, oxygen, a fluorine-based gas, an amine gas, carbon monoxide, carbon dioxide, and an alcohol gas.

In one embodiment, pre-processing the sidewall of the MTJ layer to form the modified layer with the preset thickness through the reaction at the sidewall of the MTJ layer comprises: pre-processing, when all the sidewall is exposed, the sidewall of the MTJ layer through ion beam etching to form the modified layer with the preset thickness through the reaction at the sidewall of the MTJ layer.

In one embodiment, in the ion beam etching, an incident angle of an ion beam ranges from 30° to 60°, energy of ions ranges from 30V to 100V, a bias voltage for accelerating the ions ranges from 50V to 1000V, and a flow rate of a gas ranges from 10 sccm to 500 sccm.

In one embodiment, the gas comprises one or more of: nitrogen, oxygen, and hydrogen.

In one embodiment, duration of pre-processing the sidewall of the MTJ layer through the ion beam etching is less than or equal to 120 seconds.

In one embodiment, the preset thickness of the modified layer ranges from 1 nm to 2 nm.

In one embodiment, performing the second etching comprises: performing the second etching through ion beam etching, until the substrate is exposed, where in the ion beam etching, an incident angle of an ion beam ranges from 10° to 60°, energy of ions ranges from 50V to 600V, a bias voltage for accelerating the ions ranges from 50V to 1000V, a flow rate of a gas ranges from 10 sccm to 500 sccm, and the gas comprises one or more of: an inert gas, nitrogen, oxygen, a fluorine-based gas, an amine gas, carbon monoxide, carbon dioxide, and an alcohol gas.

In one embodiment, the second etching comprises: performing the second etching through reactive ion etching, until the substrate is exposed, where in the reactive ion etching, power of a source electrode ranges from 500 W to 2000 W, power of a bias electrode ranges from 100 W to 2000 W, a pressure in an etching chamber ranges from 2 mT to 20 mT, a flow rate of a gas ranges from 10 sccm to 500 sccm, and the gas comprises one or more of: an inert gas, nitrogen, oxygen, a fluorine-based gas, an amine gas, carbon monoxide, carbon dioxide, and an alcohol gas.

Embodiments of the present disclosure are advantageous over conventional technology in at least following aspects.

According to embodiments of the present disclosure, the method for reducing the damage to the MTJ of the MRAM is provided, comprises: providing the base structure, where the base structure comprises the substrate, the lower electrode, the MTJ layer, and the upper electrode, which are arranged in the above-listed sequence along the first direction, and the first direction is perpendicular to the substrate and points from the substrate to the lower electrode; performing the first etching on the surface of the upper electrode facing away from the substrate until the lower electrode is exposed; pre-processing the sidewall of the MTJ layer to form the modified layer with the preset thickness through reaction at the sidewall of the MTJ layer; and performing the second etching until the substrate is exposed.

Herein the sidewall of the MTJ layer is pre-processed to trigger the reaction, so as to form the modified layer having the preset thickness. The modified layer is capable to scatter incident ions in subsequent etching processes, and hence minimizes the damage to the MTJ.

### BRIEF DESCRIPTION OF THE DRAWINGS

Hereinafter drawings to be applied in embodiments of the present disclosure or in conventional technology are briefly described, in order to clarify illustration of technical solutions according to embodiments of the present disclosure or in conventional technology. Apparently, the drawings in the following descriptions are only some embodiments of the present disclosure, and other drawings may be obtained by those skilled in the art based on the provided drawings without exerting creative efforts.

FIG. 1 is a schematic structural diagram of a single bin of a magnetic random access memory (MRAM).

FIG. 2 is a schematic diagram of an operation principle of a magnetic tunnel junction (MTJ).

FIG. 3 is a schematic structural diagram of a single bin of another MRAM.

FIG. 4 is a schematic diagram of a MRAM being damaged during processing, where the damage part is generally called MTJ damage.

FIG. 5 is a schematic flowchart of a method for reducing damage to a MTJ of a MRAM according to an embodiment of the present disclosure.

FIGS. 6 to 9 are schematic diagrams of partial structures corresponding to a method as shown in FIG. 5 according to an embodiment of the present disclosure.

FIG. 10 is a schematic diagram of a comparative effect between MTJ layers with and without, respectively, pre-processing according to an embodiment of the present disclosure.

### DETAILED DESCRIPTION OF EMBODIMENTS

Hereinafter technical solutions in embodiments of the present disclosure are described clearly and completely in conjunction with the drawings in embodiments of the present closure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

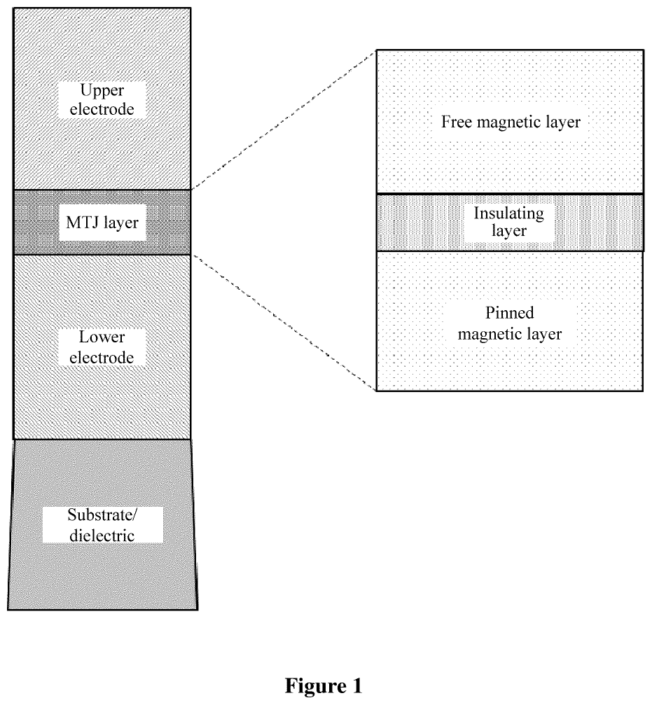

Reference is made to FIG. 1 on a basis of content in the background. FIG. 1 is a schematic structural diagram of a single bin of a magnetic random access memory (MRAM). As shown in FIG. 1, an entire MRAM structure is disposed on a substrate, and there are a lower electrode, a magnetic tunnel junction (MTJ), and an upper electrode, which are arranged in the above-listed sequence along a certain direction. The MTJ is a key structure of a MRAM device. As shown in FIG. 1, the MTJ comprises a pinned magnetic layer, an insulating layer, and a free magnetic layer, which are arranged along such direction.

The direction is perpendicular to the substrate, and points from the substrate toward the lower electrode.

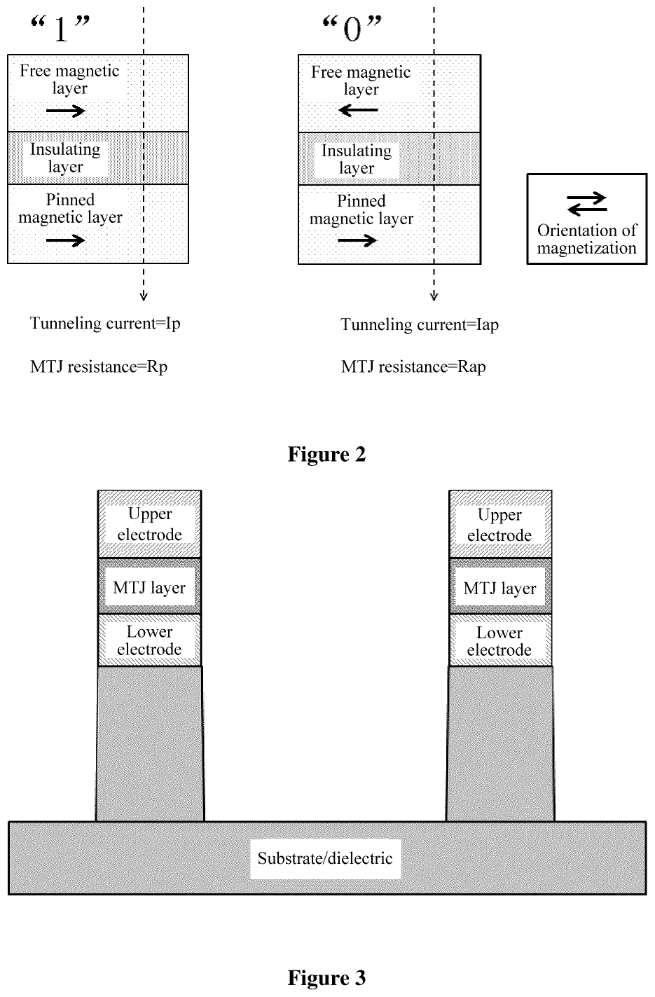

Reference is made to FIG. 2 on a basis of the MRAM structure as shown in FIG. 1. FIG. 2 is a schematic diagram of an operation principle of an MTJ. As shown in FIG. 2, when applying a voltage across the MTJ, a current is capable to pass through tunneling due to a quite small thickness (which is generally several nanometers) of the insulating layer. An orientation of magnetization in the pinned magnetic layer is fixed, and an orientation of magnetization in the free magnetic layer is switchable.

In a case that the orientation of magnetization of the pinned magnetic layer and that of the free magnetic layer are parallel, the resistance Rp of the MTJ is small, and a tunneling current Ip is large. In such case, the entire structure may be regarded as being in an on-state, which represents a bin of “1”.

In a case that the orientation of magnetization of the pinned magnetic layer and that of the free magnetic layer are anti-parallel, the resistance Rap of the MTJ is large, and the tunneling current lap is small. In such case, the entire structure may be regarded as being in an off-state, which represents a bin of “0”.

A performance of the MTJ is calibrated by tunneling magnetoresistance (TMR), of which an equation is as follows:

$$TMR = ( \frac{Rap - Rp}{Rp} )$$

The larger the TMR is, the better the performance of the MRAM is.

It is discovered that the greater a difference between the on-state resistance (Rp) and the off-state resistance (Rap) is, the better the device performance is.

The operation principle of MTJ reveals that a key factor in operation of the MTJ is ensuring good insulation of the insulating layer, which limits that electrons have the tunneling as their only passing means and cannot travel between the pinned magnetic layer and the free magnetic layer directly via the insulating layer (which causes a leak).

A performance of the insulating layer is generally calibrated by RA. In one embodiment, RA is a product of resistance (R) and an area (A) of the insulating layer. The larger the RA is, the better the device performance is.

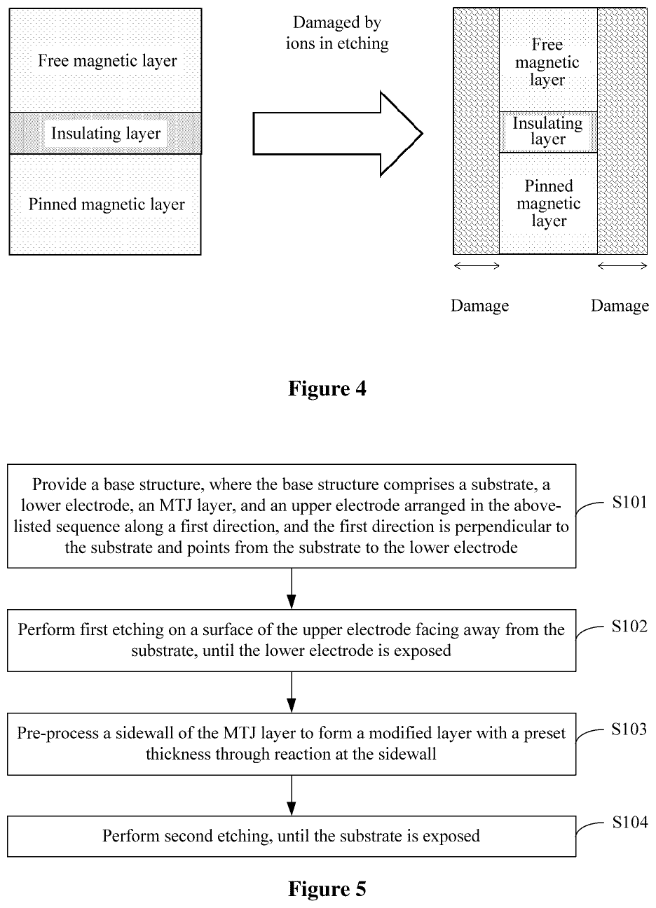

Reference is made to FIG. 3, which is a schematic structural diagram of a single bin of another MRAM. Multiple single-bin structures, as shown in FIG. 1, of the MRAM are arranged into an array and are interconnected via wiring, such that a simple MRAM storage structure as shown in FIG. 3 is formed.

As shown in FIG. 3, a trench is formed between different single-bin structures of MRAM. The trench may be regards as a part of an MTJ structure in the MRAM.

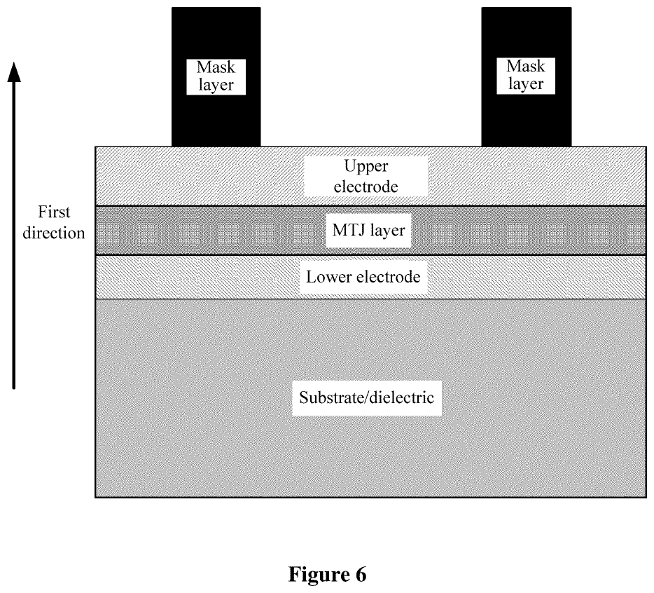

Generally, ion beam etching is performed during manufacture of the MRAM. During the ion beam etching, ions with certain energy would destroy a crystal structure at a sidewall of the MTJ layer. Reference is made to FIG. 4, which is a schematic diagram of damage induced during manufacturing an MRAM. The damaged part of the structure is usually called MTJ damage.

The MTJ damage would reduce the area (A) of the insulating layer, thereby reduces RA, which deteriorates the device performance.

In view of the above, a conventional solution is reducing energy of ions as much as possible during the etching, in order to reduce the damage. Such solution is subject to a main problem that the reduced energy of ions results in a reduced etching rate and thereby a reduced yield.

Another conventional solution is removing the MTJ damage through a chemical means. Such solution is somehow makeshift since they merely remove the already formed damage rather than reducing the damage, and the insulation layer still shrinks in such solution.

A method for reducing damage MTJ of MRAM is provided according to embodiments of the present disclosure. The MTJ damage can be greatly reduced, thereby improving the performance of MRAM device.

Hereinafter the present disclosure is further illustrated in detail in conjunction with the drawings and specific embodiments, so as clarify and elucidate the above objectives, features, and advantages of the present disclosure.

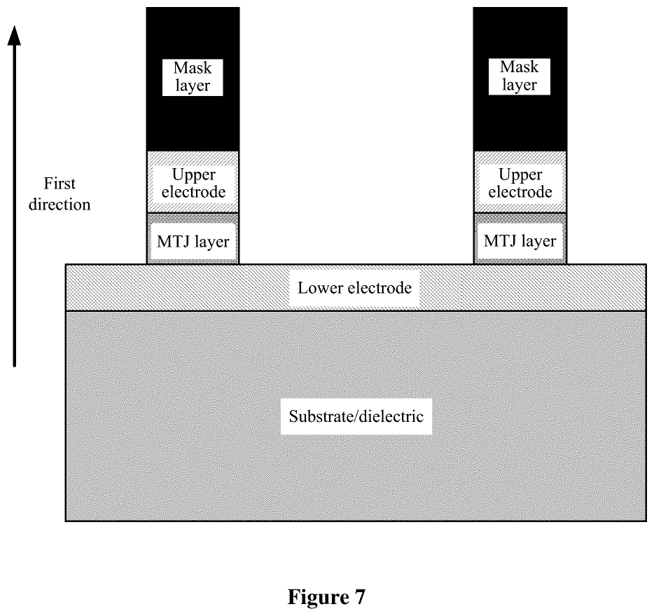

Reference is made to FIG. 5, which is a schematic flowchart of a method for reducing damage to a MTJ of a MRAM according to an embodiment of the present disclosure.

The method comprises following steps S101 to S104.

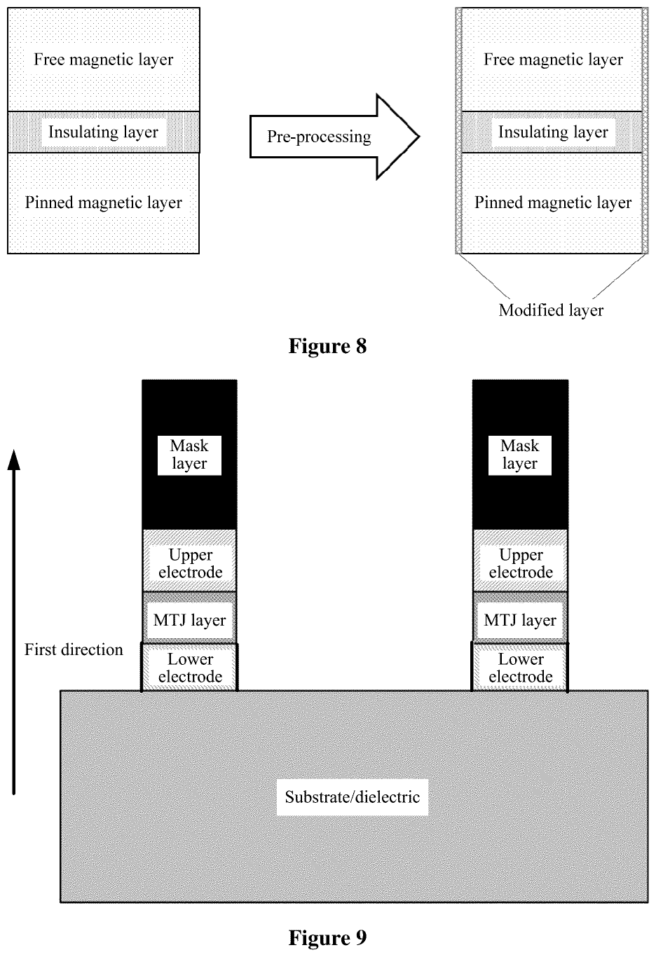

In step S101, a base structure is provided, as shown in FIG. 6. The base structure comprises a substrate, a lower electrode, an MTJ layer, and an upper electrode, which are arranged in the above-listed sequence along a first direction. The first direction is perpendicular to the substrate, and points from the substrate to the lower electrode.

In this step, a mask layer may be formed on a surface of the upper electrode facing away from the substrate, before performing subsequent first etching. The mask layer comprises multiple mask units.

That is, the mask layer is formed on the base structure, that is, on the surface of the upper electrode facing away from the MTJ layer. A material of the mask layer may be TiN, Ta, C, Si, SiO, SiN, or a combination of the above, which is not limited herein and may depend on an actual situation.

In step S102, a first etching is performed on the surface of the upper electrode facing away from the substrate until the lower electrode is exposed, as shown in FIG. 7.

In this step, a degree of the first etching needs to be determined according to an actual situation. It is ensured that the first etching stops at an interface between the MTJ layer and the lower electrode.

In one embodiment, the first etching comprises a following step. The first etching is performed on the surface of the upper electrode facing away from the substrate through ion beam etching, until the lower electrode is exposed.

That is, a means of the first etching is ion beam etching (IBE). In one embodiment, the ion beam etching is configured as follows. An incident angle of an ion beam ranges from 10° to 60°, energy of ions ranges from 50V to 600V, a bias voltage for accelerating the ions ranges from 50V to 1000V, and a flow rate of a gas ranges from 10 sccm to 500 sccm. The gas is an inert gas, nitrogen, oxygen, a fluorine-based gas, an amine gas, carbon monoxide, carbon dioxide, an alcohol gas, or a combination of the above.

In an alternative embodiment, the first etching comprises a following step. The first etching is performed on the surface of the upper electrode facing away from the substrate through reactive ion etching, until the lower electrode is exposed.

That is, a means of the first etching is reactive ion etching (RIE). In one embodiment, the reactive ion etching is configured as follows. Power of a source electrode ranges from 500 W to 2000 W, power of a bias electrode ranges from 100 W to 2000 W, a pressure in an etching chamber ranges from 2 mT to 20 mT, and a flow rate of a gas ranges from 10 sccm to 500 sccm. The gas is an inert gas, nitrogen, oxygen, a fluorine-based gas, an amine gas, carbon monoxide, carbon dioxide, an alcohol gas, or a combination of the above.

In step S103, the sidewall of the MTJ layer is pre-processed, so as to form a modified layer with a preset thickness through reaction at the sidewall, as shown in FIG. 8. In step S104, second etching is performed until the substrate is exposed, as shown in FIG. 9.

In this step, a degree of the second etching needs to be determined according to an actual situation. It is ensured that the second etching stops at an interface between the lower electrode and the substrate.

In one embodiment, the second etching comprises a following step. The second etching is performed through ion beam etching, until the substrate is exposed.

That is, a means of the second etching is ion beam etching (IBE). In one embodiment, the ion beam etching is configured as follows. An incident angle of an ion beam ranges from 10° to 60°, energy of ions ranges from 50V to 600V, a bias voltage for accelerating the ions ranges from 50V to 1000V, and a flow rate of a gas ranges from 10 sccm to 500 sccm. The gas is an inert gas, nitrogen, oxygen, a fluorine-based gas, an amine gas, carbon monoxide, carbon dioxide, an alcohol gas, or a combination of the above.

In an alternative embodiment, the second etching comprises a following step. The second etching is performed through reactive ion etching, until the substrate is exposed.

That is, a means of the first etching is reactive ion etching (RIE). In one embodiment, the reactive ion etching is configured as follows. Power of a source electrode ranges from 500 W to 2000 W, power of a bias electrode ranges from 100 W to 2000 W, a pressure in an etching chamber ranges from 2 mT to 20 mT, and a flow rate of a gas ranges from 10 sccm to 500 sccm. The gas is an inert gas, nitrogen, oxygen, a fluorine-based gas, an amine gas, carbon monoxide, carbon dioxide, an alcohol gas, or a combination of the above.

Herein the sidewall of the MTJ layer is pre-processed, such that reaction at the sidewall of the MTJ layer forms the modified layer with the preset thickness. The modified layer is capable scatter incident ions in subsequent etching, so as to minimize the MTJ damage.

In one embodiment, preprocessing the sidewall of the MTJ layer to form the modified layer through the reaction at the sidewall comprises a following step. The sidewall of the MTJ layer is processed through ion beam etching to form the modified layer through the reaction at the sidewall, after the whole sidewall is exposed.

In one embodiment, the ion beam etching is configured as follows. An incident angle of an ion beam ranges from 30° to 60°, energy of ions ranges from 30V to 100V, a bias voltage for accelerating the ions ranges from 50V to 1000V, and a flow rate of a gas ranges from 10 sccm to 500 sccm.

In one embodiment, the gas for the ion beam etching is nitrogen, oxygen, hydrogen, or a combination of the above.

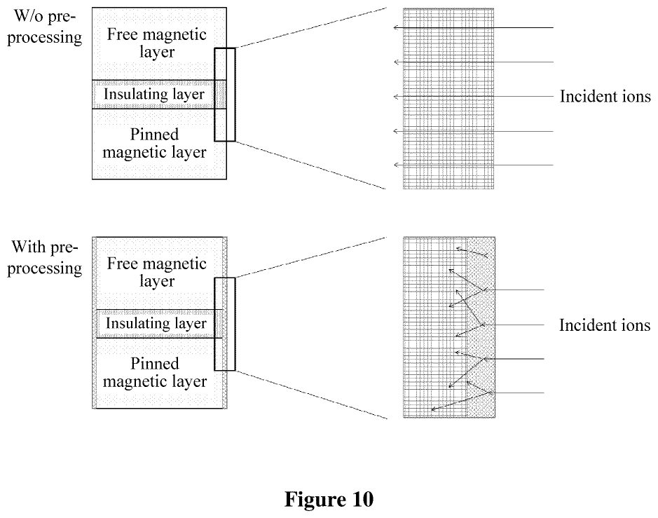

Reference is made to FIG. 10, which is a schematic diagram of a comparative effect between MTJ layers with or without, respectively, pre-processing according to an embodiment of the present disclosure. As shown in FIG. 10, a lattice structure of the sidewall of the MTJ layer without the pre-processing is regular in arrangement, and the incident ions in subsequent etching is highly like to travel deep via the lattice. Such phenomenon is called the passage effect. In such case, the incident ions in subsequent etching would induce deep MTJ damage into the MTJ layer.

In comparison, the lattice structure of the sidewall of the MTJ layer subject to pre-processing has been altered under nitrogen, oxygen, hydrogen, or a combination of the above, and thus the modified layer with the preset thickness has been formed. The incident ions in subsequent etching can be scattered in the modified layer, which weakens the passage effect. Thereby, the MTJ damage is reduced, and the device performance is improved.

In one embodiment, duration of pre-processing the sidewall through the ion beam etching is less than or equal to 120 seconds.

In this embodiment, the duration of pre-processing the sidewall through the ion beam etching is controlled, so as to control the thickness of the modified layer. Thereby, an optimal thickness can be achieved.

In a case that the etching duration is greater than 120 seconds, the thickness of the modified layer is too large and introduces the actual MTJ damage. Hence, the etching duration is controlled to be appropriate, such that the final thickness of the modified layer can prevent expansion of the MTJ damage in subsequent processing to the greatest extent.

In one embodiment, the thickness of the modified layer ranges from 1 nm to 2 nm.

Herein the substrate may be a dielectric layer made of multiple materials, and hence it is denoted as “substrate/dielectric” in the drawings. A specific material of the substrate is not limited herein.

Hereinabove the method for reducing the damage to the MTJ of the MRAM according embodiments of the present disclosure is illustrated in detail. Specific embodiments are utilized herein to illustrate principles and implementations of the present disclosure. The description of the above embodiments is only intended for helping understand the method and core concepts of the present disclosure. Those skilled in the art may make modifications on specific implementations and application scenarios based on the concepts of the present disclosure. In summary, content of the present disclosure should not be construed as limitations of the present disclosure.

The embodiments of the present disclosure are described in a progressive manner, and each embodiment places emphasis on the difference from other embodiments. Therefore, one embodiment can refer to other embodiments for the same or similar parts. Since apparatuses disclosed in the embodiments correspond to methods disclosed in the embodiments, the description of the apparatuses is simple, and reference may be made to the relevant part of the methods.

The relationship terms such as “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, a method, an article or a device including a series of elements include not only the disclosed elements but also other elements that are not clearly enumerated, or further include inherent elements of the process, the method, the article or the device. Unless expressively limited, the statement “including a . . . ” does not exclude the case that other similar elements may exist in the process, the method, the article or the device other than enumerated elements.

According to the description of the disclosed embodiments, those skilled in the art can implement or use the present disclosure. Various modifications made to these embodiments may be obvious to those skilled in the art, and the general principle defined herein may be implemented in other embodiments without departing from the spirit or scope of the present disclosure. Therefore, the present disclosure is not limited to the embodiments described herein but conforms to a widest scope in accordance with principles and novel features disclosed in the present disclosure.

1. A method for reducing damage to a magnetic tunnel junction (MTJ) of a magnetic random access memory (MRAM), comprising:
providing a base structure, wherein the base structure comprises a substrate, a lower electrode, an MTJ layer, and an upper electrode, which are arranged in the above-listed sequence along a first direction, and the first direction is perpendicular to the substrate and points from the substrate to the lower electrode;
performing first etching on a surface of the upper electrode facing away from the substrate until the lower electrode is exposed;
pre-processing a sidewall of the MTJ layer to form a modified layer with a preset thickness through reaction at the sidewall of the MTJ layer; and
performing second etching until the substrate is exposed.

2. The method according to claim 1, wherein performing the first etching comprises:
performing the first etching on the surface of the upper electrode through ion beam etching, until the lower electrode is exposed, wherein in the ion beam etching:
an incident angle of an ion beam ranges from 10° to 60°,
energy of ions ranges from 50 eV to 600 eV,
a bias voltage for accelerating the ions ranges from 50V to 1000V,
a flow rate of a gas ranges from 10 sccm to 500 sccm, and
the gas comprises one or more of: an inert gas, nitrogen, oxygen, a fluorine-based gas, an amine gas, carbon monoxide, carbon dioxide, and an alcohol gas.

3. The method according to claim 1, wherein performing the first etching comprises:
performing the first etching on the surface of the upper electrode through reactive ion etching, until the lower electrode is exposed, wherein in the reactive ion etching:
power of a source electrode ranges from 500 W to 2000 W,
power of a bias electrode ranges from 100 W to 2000 W,
a pressure in an etching chamber ranges from 2 mT to 20 mT,
a flow rate of a gas ranges from 10 sccm to 500 sccm, and
the gas comprises one or more of: an inert gas, nitrogen, oxygen, a fluorine-based gas, an amine gas, carbon monoxide, carbon dioxide, and an alcohol gas.

4. The method according to claim 1, wherein pre-processing the sidewall of the MTJ layer to form the modified layer with the preset thickness through the reaction at the sidewall of the MTJ layer comprises:
pre-processing, when all the sidewall is exposed, the sidewall of the MTJ layer through ion beam etching to form the modified layer with the preset thickness through the reaction at the sidewall of the MTJ layer.

5. The method according to claim 4, wherein in the ion beam etching:
an incident angle of an ion beam ranges from 30° to 60°,
energy of ions ranges from 30V to 100V,
a bias voltage for accelerating the ions ranges from 50 eV to 1000 eV, and
a flow rate of a gas ranges from 10 sccm to 500 sccm.

6. The method according to claim 4, wherein the gas comprises one or more of: nitrogen, oxygen, and hydrogen.

7. The method according to claim 4, wherein duration of pre-processing the sidewall of the MTJ layer through the ion beam etching is less than or equal to 120 seconds.

8. The method according to claim 4, wherein the preset thickness of the modified layer ranges from 1 nm to 2 nm.

9. The method according to claim 1, wherein performing the second etching comprises:
performing the second etching through ion beam etching, until the substrate is exposed, wherein in the ion beam etching:
an incident angle of an ion beam ranges from 10° to 60°,
energy of ions ranges from 50 eV to 600 eV,
a bias voltage for accelerating the ions ranges from 50V to 1000V,
a flow rate of a gas ranges from 10 sccm to 500 sccm, and
the gas comprises one or more of: an inert gas, nitrogen, oxygen, a fluorine-based gas, an amine gas, carbon monoxide, carbon dioxide, and an alcohol gas.

10. The method according to claim 1, wherein the second etching comprises:
performing the second etching through reactive ion etching, until the substrate is exposed, wherein in the reactive ion etching:
power of a source electrode ranges from 500 W to 2000 W,
power of a bias electrode ranges from 100 W to 2000 W,
a pressure in an etching chamber ranges from 2 mT to 20 mT,
a flow rate of a gas ranges from 10 sccm to 500 sccm, and
the gas comprises one or more of: an inert gas, nitrogen, oxygen, a fluorine-based gas, an amine gas, carbon monoxide, carbon dioxide, and an alcohol gas.

11. An apparatus for reducing damage to a magnetic tunnel junction (MTJ) of a magnetic random access memory (MRAM), comprising:
a memory storing computer-readable instructions, and
a processor, wherein the computer-readable instructions when executed by the processor configure the apparatus to perform:
providing a base structure, wherein the base structure comprises a substrate, a lower electrode, an MTJ layer, and an upper electrode, which are arranged in the above-listed sequence along a first direction, and the first direction is perpendicular to the substrate and points from the substrate to the lower electrode;
performing first etching on a surface of the upper electrode facing away from the substrate until the lower electrode is exposed;
pre-processing a sidewall of the MTJ layer to form a modified layer with a preset thickness through reaction at the sidewall of the MTJ layer; and
performing second etching until the substrate is exposed.

12. A non-transitory computer-readable storage medium, storing computer-readable instructions, wherein the computer-readable instructions when executed by a processor configure an apparatus for reducing damage to a magnetic tunnel junction (MTJ) of a magnetic random access memory (MRAM) to perform:
providing a base structure, wherein the base structure comprises a substrate, a lower electrode, an MTJ layer, and an upper electrode, which are arranged in the above-listed sequence along a first direction, and the first direction is perpendicular to the substrate and points from the substrate to the lower electrode;
performing first etching on a surface of the upper electrode facing away from the substrate until the lower electrode is exposed;
pre-processing a sidewall of the MTJ layer to form a modified layer with a preset thickness through reaction at the sidewall of the MTJ layer; and
performing second etching until the substrate is exposed.
